(19) United States
(12) Patent Application Publication
(10) Pub. No.: US 2013/0178012 A1
(43) Pub. Date: Jul. 11, 2013

(54) METHOD FOR MANUFACTURING A GATE-CONTROL DIODE SEMICONDUCTOR DEVICE

(71) Applicants: Pengfei Wang, Shanghai (CN); Xiaoyong Liu, Shanghai (CN); Qingqing Sun, Shanghai (CN); Wei Zhang, Shanghai (CN)

(72) Inventors: Pengfei Wang, Shanghai (CN); Xiaoyong Liu, Shanghai (CN); Qingqing Sun, Shanghai (CN); Wei Zhang, Shanghai (CN)

(21) Appl. No.: 13/534,973

(22) Filed: Jun. 27, 2012

(30) Foreign Application Priority Data
Jan. 5, 2012 (CN) CN 201210001479.1

(51) Int. Cl. H01L 21/336

(52) U.S. Cl. 438/104; 257/E21.411

(57) ABSTRACT

This invention belongs to semiconductor device manufacturing field and discloses a method for manufacturing a gate-control diode semiconductor device. When the gate voltage is relatively high, the channel under the gate is of n-type and the device is of a simple gate-control pn junction structure; by way of controlling the effective n-type concentration of the ZnO film through back-gate control, inverting the n-type ZnO into p-type through the gate, and using NiO as a p-type semiconductor, an n-p-n-p doping structure is formed. The method features capacity of manufacturing gate-control diode devices able to reduce chip power consumption through the advantages of high driving current and small sub-threshold swing. The present invention using a low temperature process production is especially applicable to the manufacturing of semiconductor devices based on flexible substrates and reading & writing devices that have a flat panel display and phase change memory.

### CROSS-REFERENCE TO RELATED APPLICATION

This application claims priority to Chinese Patent Application No. CN 201210001479.1 filed on Jan. 5, 2012, the entire content of which is incorporated by reference herein.

### BACKGROUND OF THE INVENTION

1. Technical Field

The present invention belongs to the technical field of semiconductor device manufacturing, relates to a method for manufacturing a semiconductor device, and more especially, to a method for manufacturing a gate-control diode semiconductor device.

2. Description of Related Art

The Metal-Oxide-Semiconductor Field Effect Transistor (MOSFET) is a kind of field effect transistor capable of being widely used in analog circuits and digital circuits, of which the basic structure is as shown in FIG. 1, including a silicon substrate 101, a gate insulation layer 104 and a gate conductive layer 105 formed on the silicon substrate 101, wherein a drain region 102 and a source region 103 are arranged on both sides of the gate in substrate 101. When a large enough potential difference is applied between the gate and the source of the MOSFET, the electric field will form induced charges on the surface of the silicon substrate under the gate insulation layer, thus a so-called “inversion channel” is formed. The channel polarity is the same with that of the drain and source. Assume that the drain and the source are of n type, the channel is also of n type. After the formation of the channel, the MOSFET can allow current to pass through it. The current value passing through the channel of the MOSFET will vary with the voltage values applied on the gate.

With the continuous development of the integrated circuit, the size of the MOSFET becomes smaller and smaller, and the transistor density on the unit array becomes higher and higher. Today, the technology node of integrated circuit devices is about 45 nm and the leakage current between the source and the drain of the MOSFET is increasing rapidly with the decrease of channel length. Moreover, the minimum sub-threshold swing (SS) of the traditional MOSFET is limited to 60 mv/dec, which restricts the opening and closing speed of the transistor. On some chips of high integration density, the reduction of the device size means greater SS value. However, the high-speed chips require smaller SS value to improve the device frequency as well as reduce the chip power consumption. Therefore, when the channel length of the device decreases to smaller than 30 nm, a new-type device shall be used to obtain a smaller leakage current and SS value, thus decreasing the chip power consumption.

### BRIEF SUMMARY OF THE INVENTION

In view of this, the present invention aims at providing a method for manufacturing a gate-control diode semiconductor device capable of reducing the leakage current and the SS value so as to reduce the chip power consumption.

The memory device provided in the present invention adopts the positive feedback automatic gain principle. Namely, when the doping type of a planar semiconductor device is p-n-p-n, two pairs of interdependent triodes, p-n-p and n-p-n, are generated. Usually, the two triodes can be magnified mutually, which may cause the increase of the device current and further cause the breakdown of the device in severe cases. To apply this characteristic into thin-film semiconductors, a gate-control diode semiconductor memory based on the ZnO semiconductor material is provided in the present invention. When the gate voltage is high and the channel under the gate is of n type, the device has a simple gate-control pn junction structure. By way of controlling the effective n type concentration of the ZnO film through back-gate control, inverting the n-type ZnO to p-type through the gate and using NiO as a p-type semiconductor, an n-p-n-p doping structure is formed.

A method for manufacturing the gate-control diode semiconductor above is provided in the present invention, including the following steps:

provide a heavily-doped n-type silicon substrate;

form a first kind of insulation film on the n-type silicon substrate;

form a ZnO layer on the first kind of insulation film;

etch the ZnO layer to form an active region;

cover the active region to form a NiO layer doped with p-type impurity ions;

photoetch a pattern, etch the NiO layer and preserve the NiO layer on one side of the ZnO active region to form a device source;

deposit a second kind of insulation film on the exposed NiO and ZnO surfaces;

define the contact holes of the drain and the source by photoetching and etching the second kind of insulation film and keep the second kind of insulation film of the area separate from the contact holes, wherein the contact holes of the drain and the source are on both sides of the active region respectively, namely on the NiO and the ZnO on the other side respectively.

Form a first kind of conductive film through deposition and etch the first kind of conductive film to form a drain electrode, a gate electrode and a source electrode which are independent of one another, wherein the drain electrode contacts with the ZnO on the other side of the active region through the drain contact hole and the gate electrode is on the non-etched second insulation film between the contact holes of the source and the drain.

Furthermore, the first kind of insulation film is of silicon oxide and has a thickness of 1-500 nm. The second kind of insulation film is of SiO₂ or high dieletric constant material HfO₂. The first conductive film is of heavily-doped polycrystalline silicon, copper, tungsten, aluminum, titanium nitride or tantalum nitride.

The method for manufacturing a gate-control diode semiconductor device provided in the present invention features a simple process, low manufacturing cost and capacity of manufacturing gate-control diode devices able to reduce the chip power consumption through advantages of high driving current and small sub-threshold swing. Moreover, the present invention using a low temperature process production is especially applicable to the manufacturing of semiconductor devices based on flexible substrates and reading & writing devices having flat panel displays and phase change memories.

### BRIEF DESCRIPTION OF THE SEVERAL VIEWS OF THE DRAWINGS

FIG. 1 is the sectional view of the traditional MOSFET.

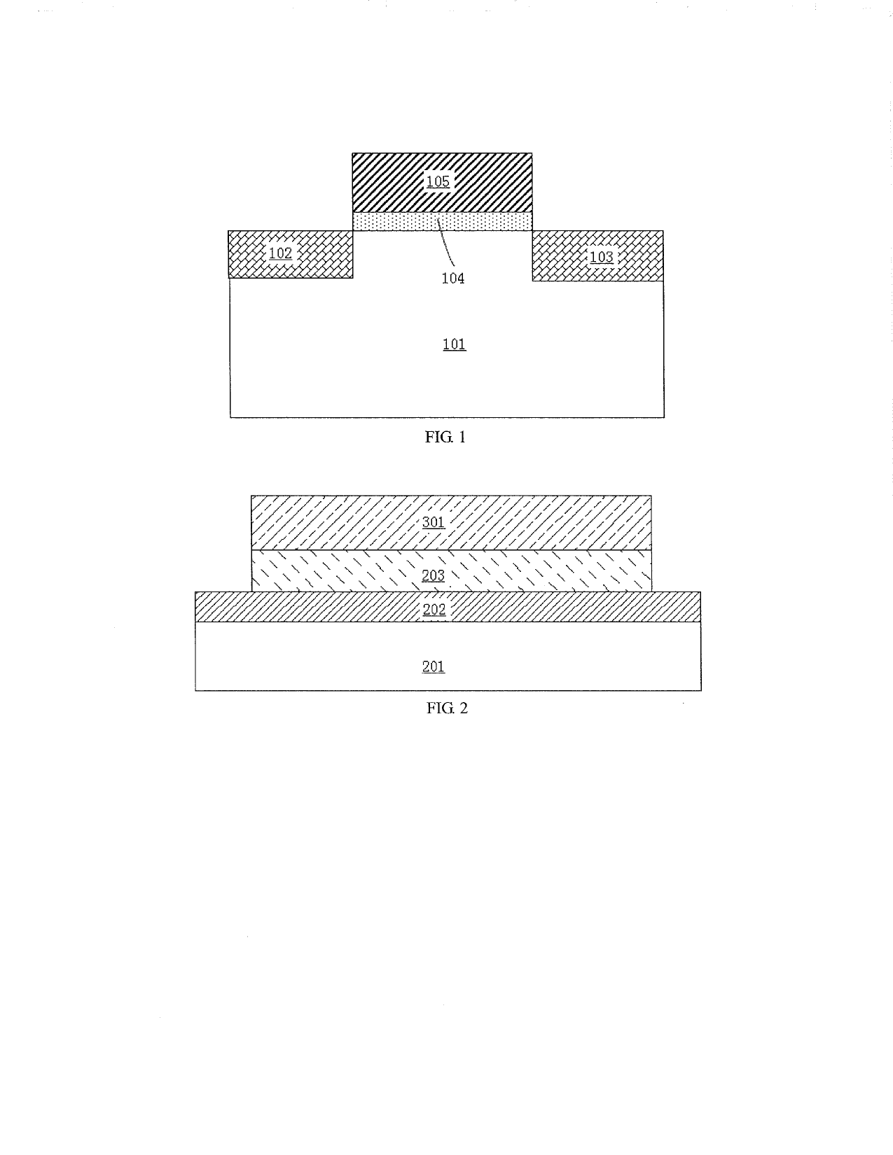

FIGS. 2-5 are the process flow diagrams of an embodiment of the method for manufacturing a gate-control diode semiconductor device disclosed in the present invention.

FIG. 6 is the schematic diagram of the structure of an embodiment in cut-off state of the gate-control diode device manufactured by using the method provided in the present invention.

### DETAILED DESCRIPTION OF THE INVENTION

An exemplary embodiment of the present invention is further detailed herein by referring to the drawings. In the drawings, the thicknesses of the layers and regions are either zoomed in or out for the convenience of description, so they shall not be considered as the true size. Although these drawings cannot accurately reflect the true size of the device, they still reflect the relative positions among the regions and composition structures completely, especially the up-down and adjacent relations.

The reference diagrams are the schematic diagrams of the idealized embodiments of the present invention, so the embodiments shown in the present invention shall not be limited to specific shapes in areas shown in the drawings, while they shall include the obtained shapes such as the deviation caused by manufacturing. For instance, curves obtained through etching are often bent or rounded, while in the embodiments of the present invention, they are all presented in rectangles, and what the drawings present is schematic and shall not be considered as the limit to the present invention. Meanwhile, the term “substrate” used in the following description can be considered as a semiconductor substrate during manufacturing process, and other film layers prepared on it may also be included.

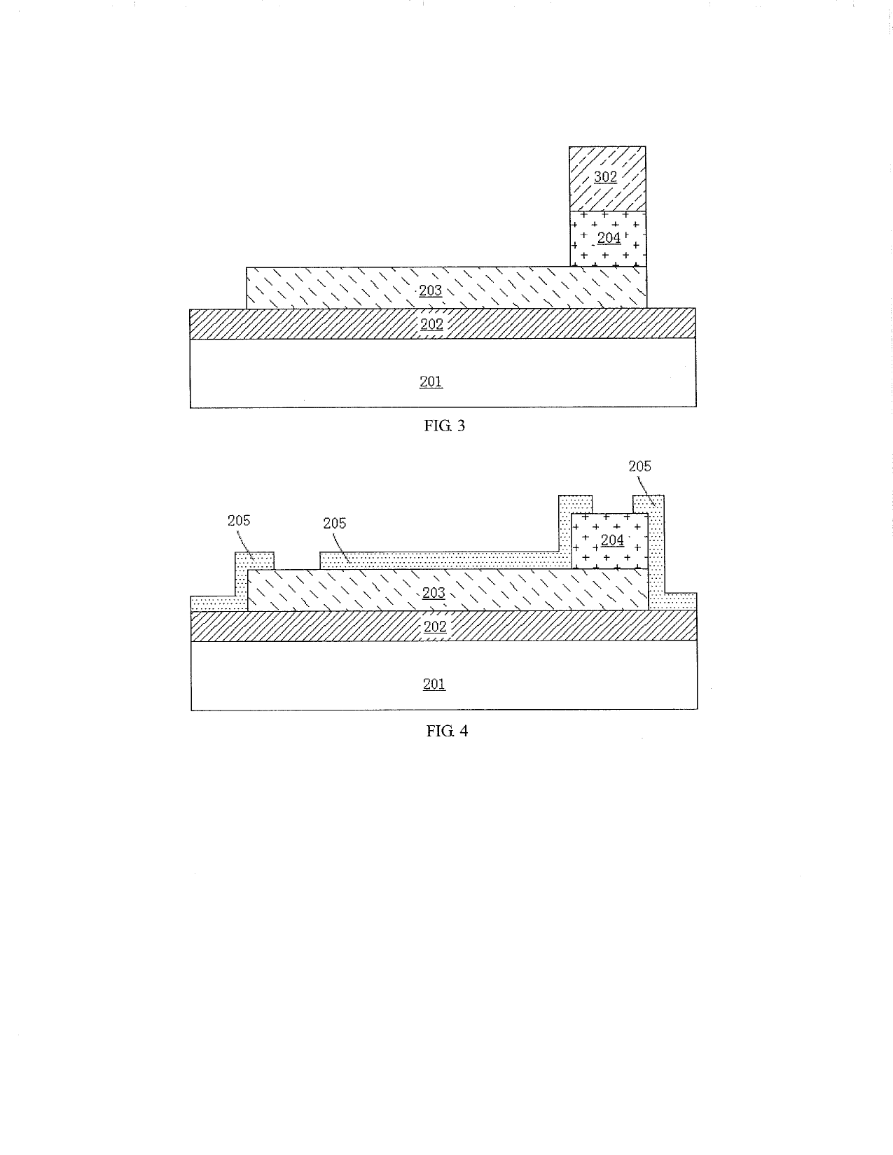

Firstly, develop a silicon oxide film 202 with a thickness of 20 nm on a provided silicon substrate 201 heavily doped with n-type impurity ions through thermal oxidization, and then deposit a ZnO film 203 with a thickness of 5 nm on the silicon oxide film 202 by atomic layer deposition. Afterwards, deposit a layer of photoresist 301 and form a pattern through masking film, exposal and development, and then etch the ZnO film 203 to form an active region, as shown in FIG. 2.

After removing the photoresist 301, deposit a NiO film doped with p-type impurity ions through Physical Vapor Deposition (PVD), then deposit another layer of phototresist 302, form a pattern through masking film, exposal and development, and etch the NiO film to form a device source 204, as shown in FIG. 3.

After removing the photoresist 302, deposit a layer of high dieletric constant materials 205 such as HfO₂, then deposit a new layer of photoresist, form a pattern though masking film, exposal and development, and etch the high dieletric constant material 205 to define the positions of the drain and the source. The construction after removing the photoresist is as shown in FIG. 4.

Finally, deposit a metal conductive film such as aluminum and then form a drain electrode 206, a gate electrode 207 and a source electrode 208 through photoetching and etching, as shown in FIG. 5.

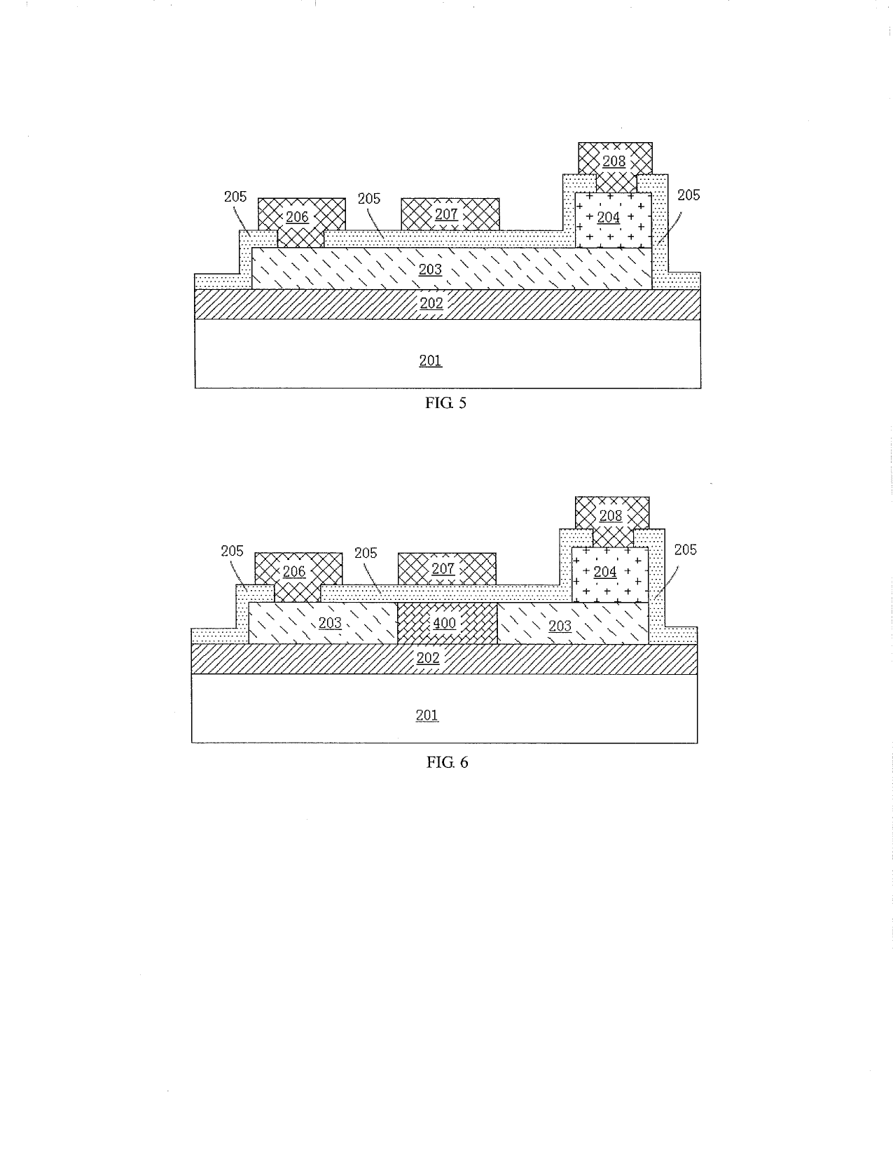

Since ZnO has the characteristics of n-type semiconductors, when the source and drain are applied with a forward bias, the device structure is equivalent to a forward-biased P+N junction structure and the device is conductive if the gate is applied with positive voltage. If the gate has a negative voltage applied, a p-type region 400 is formed in the ZnO dielectric layer 203 under the gate electrode 207, as shown in FIG. 6, the device is equivalent to a p-n-p-n junction structure and is cut off

As described above, without deviating from the spirit and scope of the present invention, there may be many significantly different embodiments. It shall be understood that the present invention is not limited to the specific embodiments described in the Specification except those limited by the Claims herein.

What is claimed is:

1. A method for manufacturing a gate-control diode semiconductor device, characterized in that it includes the following steps:
provide a heavily-doped n-type silicon substrate;
form a first kind of insulation film on the n-type silicon substrate;
form a ZnO layer on the first kind of insulation film;
etch the ZnO layer to form an active region;
cover the active region to form a NiO layer doped with p-type impurity ions;
photoetch a pattern, etch the NiO layer and preserve the NiO layer on one side of the ZnO active region to form a device source;
deposit a second kind of insulation film on the exposed NiO and ZnO surfaces;
define the contact holes of the drain and the source by photoetching and etching the second kind of insulation film and keep the second kind of insulation film of the area separate from the contact holes, wherein the contact holes of the drain and the source are on both sides of the active region respectively, namely on the NiO of one side and the ZnO of the other side respectively;
form a first kind of conductive film through deposition and etch the first kind of conductive film to form a drain electrode, a gate electrode and a source electrode which are independent of one another, wherein the drain electrode makes contact with the ZnO on the other side of the active region through the drain contact hole and the gate electrode is on the non-etched second insulation film between the contact holes of the source and the drain.

2. The method for manufacturing a gate-control diode semiconductor device according to claim 1, characterized in that the first kind of insulation film is of silicon oxide and has a thickness of 1-500 nm.

3. The method for manufacturing a gate-control diode semiconductor device according to claim 1, characterized in that the thickness of the ZnO dielectric layer is 1-100 nm.

4. The method for manufacturing a gate-control diode semiconductor device according to claim 1, characterized in that the second kind of insulation film is of SiO₂ or high dieletric constant material HfO₂.

5. The method for manufacturing a gate-control diode semiconductor device according to claim 1, characterized in that the first kind of conductive film is of heavily-doped polycrystalline silicon, copper, tungsten, aluminum, titanium nitride or tantalum nitride.
